(19) United States
(12) Patent Application Publication
(10) Pub. No.: US 2006/0050563 A1
(43) Pub. Date: Mar. 9, 2006

(54) Display device and driving method thereof

(76) Inventor: Gyu-Su Lee, Suwon-si (KR)

Correspondence Address: CANTOR COLBURN, LLP, 55 GRIFFIN ROAD SOUTH, BLOOMFIELD, CT, 06002, US

(21) Appl. No.: 11/188,063

(22) Filed: Jul. 22, 2005

(30) Foreign Application Priority Data
Sep. 9, 2004 (KR) 10-2004-0072223

(51) Int. Cl. G11C 11/34

(52) U.S. Cl. 365/185.22

(57) ABSTRACT

A display device includes gate lines transmitting a first gate-on voltage and a second gate-on voltage, data lines transmitting data voltages, pixels including switching elements and pixel electrodes, a gate driver electrically connected to the gate lines and sequentially applying the first and second gate-on voltages to the gate lines, and a data driver applying the data voltages to the data lines. The second gate-on voltage has a magnitude different with a magnitude of the first gate-on voltage. The switching elements are electrically connected to corresponding ones of the gate lines and the data lines. The switching elements are configured to turn on in response to the first and second gate-on voltages. The pixel electrodes are supplied with the data voltages. The gate driver outputs the first gate-on voltage before the second gate-on voltage.

This application claims priority to Korean Patent Application No. 10-2004-0072223, filed on Sep. 9, 2004, the contents of which in its entirety are herein incorporated by reference.

### BACKGROUND OF THE INVENTION

(a) Field of the Invention

The present invention relates to a liquid crystal display device and a driving method of the liquid crystal display device.

(b) Description of Related Art

A liquid crystal display (LCD) device includes two panels provided with field generating electrodes and a liquid crystal (LC) layer having dielectric anisotropy, which is disposed between the two panels. The field generating electrodes generally include pixel electrodes and a common electrode. The pixel electrodes are arranged in a matrix and connected to switching elements such as thin film transistors (TFTs) to be supplied with data voltages. The common electrode covers an entire surface of one of the two panels and is supplied with a common voltage. A pair of field generating electrodes that generate an electric field in cooperation with each other and the LC layer disposed therebetween form an LC capacitor that is a basic element of a pixel along with a switching element.

The LCD device applies voltages to the field generating electrodes to generate the electric field in the LC layer, and a strength of the electric field can be controlled by adjusting a voltage across the LC capacitor. Since the voltage across the LC capacitor determines an orientation of LC molecules and molecular orientations of the LC molecules determine a transmittance of light passing through the LC layer, the transmittance of light is adjusted by controlling the applied voltages to obtain desired images.

In order to prevent image deterioration due to long-time application of a unidirectional electric field, a polarity of data voltages with respect to the common voltage is reversed every frame, every row, or every pixel.

Polarity inversion of the data voltages increases a charging time of the LC capacitor since a response time of liquid crystal is relatively slow. Therefore, it takes a long time for the LC capacitor to reach a target luminance (or target voltage) causing images displayed by the LCD device to be unclear and blurred.

In order to solve this problem, impulsive driving that inserts a black image for a short time between normal images has been developed.

The impulsive driving includes an impulsive emission type driving that periodically lights off a backlight lamp to yield black images and a cyclic resetting type driving that periodically applies a black data voltage to force pixels into a black state between applications of normal data voltages.

Unfortunately, the above mentioned driving techniques do not sufficiently compensate for long response times of the liquid crystal and response times of the backlight lamp also remain long. Therefore, afterimages and flickering are generated, which deteriorate image quality. In addition, the cyclic resetting type driving may decrease a time for applying normal data voltages for displaying normal images such that the LC capacitor does not reach a target luminance.

### SUMMARY OF THE INVENTION

A motivation of the present invention is to solve the problems of conventional techniques.

A display device is provided, which includes gate lines transmitting a first gate-on voltage and a second gate-on voltage, data lines transmitting data voltages, pixels including switching elements and pixel electrodes, a gate driver electrically connected to the gate lines and sequentially applying the first and second gate-on voltages to the gate lines, and a data driver applying the data voltages to the data lines. A magnitude of the second gate-on voltage is different than a magnitude of the first gate-on voltage. The switching elements are electrically connected to corresponding ones of the gate lines and the data lines. The switching elements are configured to turn on in response to the first and second gate-on voltages. The gate driver outputs the first gate-on voltage before the second gate-on voltage.

A driving method of a display device including switching elements electrically connected to gate lines and data lines and pixel electrodes electrically connected to the switching elements is provided. The driving method includes applying first data voltages to the data lines, applying the first data voltages to the pixel electrodes through the switching elements by applying a first gate-on voltage to the gate lines, applying second data voltages to the data lines, and applying the second data voltages to the pixel electrodes through the switching elements by applying a second gate-on voltage to the gate lines. A magnitude of the first gate-on voltage is different from a magnitude of the second gate-on voltage.

### BRIEF DESCRIPTION OF THE DRAWINGS

The present invention will become more apparent by describing exemplary embodiments thereof in detail with reference to the accompanying drawings in which:

FIG. 1 is a block diagram of an LCD device according to an exemplary embodiment of the present invention;

FIG. 2 is an equivalent circuit diagram of a pixel of an LCD device according to an exemplary embodiment of the present invention;

FIG. 3 illustrates waveforms of a vertical synchronization signal and horizontal synchronization signal when image signals are applied according to an exemplary embodiment of the present invention;

FIG. 4 illustrates waveforms of a data voltage, a vertical synchronization signal and gate signals used in an LCD device according to an exemplary embodiment of the present invention;

FIG. 5 illustrates a variation of a pixel electrode voltage with respect to a data voltage, when precharging gate-on voltages and a normal charging gate-on voltage are applied according to an exemplary embodiment of the present invention;

FIG. 6 is a block diagram of an LCD device according to another exemplary embodiment of the present invention; and

FIG. 7 illustrates waveforms of a vertical synchronization signal and gate signals used in an LCD device according to another exemplary embodiment of the present invention.

### DETAILED DESCRIPTION OF THE INVENTION

The present invention now will be described more fully hereinafter with reference to the accompanying drawings, in which exemplary embodiments of the invention are shown. This invention may, however, be embodied in many different forms and should not be construed as limited to the embodiments set forth herein.

In the drawings, the thickness of layers and regions are exaggerated for clarity. Like numerals refer to like elements throughout. It will be understood that when an element such as a layer, film, region, substrate or panel is referred to as being “on” another element, it can be directly on the other element or intervening elements may also be present. In contrast, when an element is referred to as being “directly on” another element, there are no intervening elements present.

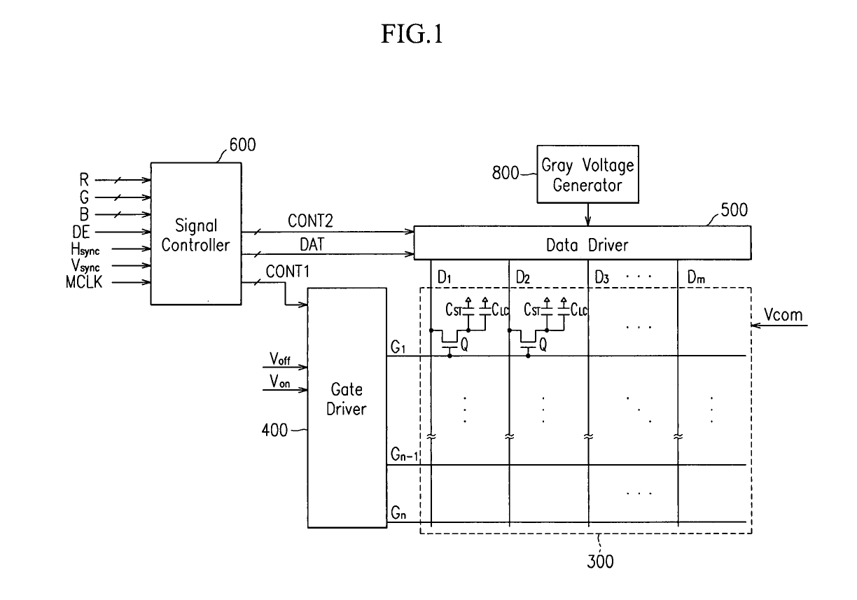

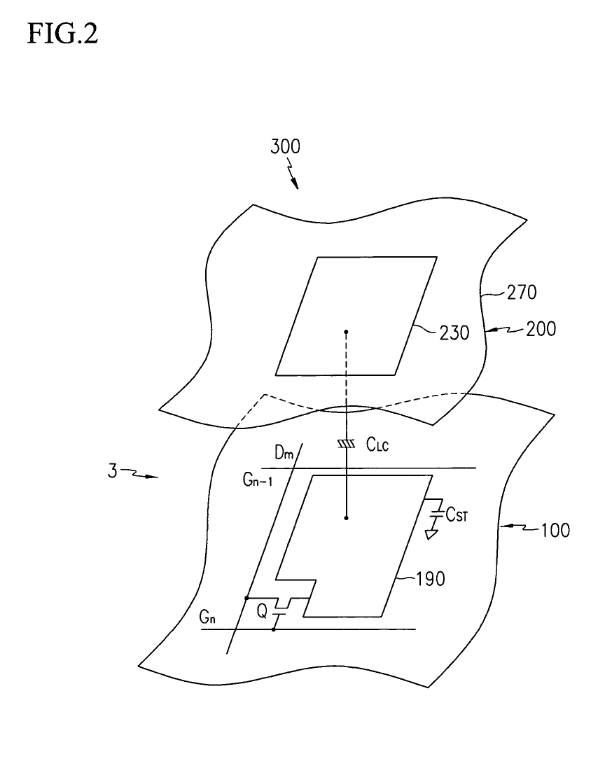

FIG. 1 is a block diagram of a liquid crystal display (LCD) device according to an exemplary embodiment of the present invention, and FIG. 2 is an equivalent circuit diagram of a pixel of an LCD device according to an exemplary embodiment of the present invention.

Referring to FIG. 1, an LCD device according to this embodiment includes a liquid crystal (LC) panel assembly 300, a gate driver 400 and a data driver 500 that are electrically connected to the panel assembly 300, a gray voltage generator 800 electrically connected to the data driver 500, and a signal controller 600 controlling the above elements.

Referring still to FIG. 1, the panel assembly 300 includes display signal lines G₁-Gₙ and D₁-Dₘ and pixels electrically connected to corresponding ones of the display signal lines G₁-Gₙ and D₁-Dₘ and arranged substantially in a matrix. In a structural view shown in FIG. 2, the panel assembly 300 includes a lower panel 100, an upper panel 200 and an LC layer 3 interposed between the lower and upper panels 100 and 200.

The display signal lines G₁-Gₙ and D₁-Dₘ are disposed on the lower panel 100 and include gate lines G₁-Gₙ transmitting gate signals (also referred to as “scanning signals”), and data lines D₁-Dₘ transmitting data signals. The gate lines G₁-Gₙ extend substantially in a row direction of the panel assembly 300 and are substantially parallel to each other, while the data lines D₁-Dₘ extend substantially in a column direction of the panel assembly 300 and are substantially parallel to each other.

Each pixel includes a switching element Q electrically connected to selected ones of the display signal lines G₁-Gₙ and D₁-Dₘ, and an LC capacitor C_{LC} and a storage capacitor C_{ST} that are electrically connected to the switching element Q. If unnecessary, the storage capacitor C_{ST} may be omitted.

The switching element Q, including for example, a thin film transistor (TFT), is provided on the lower panel 100 and has three terminals: a control terminal electrically connected to one of the gate lines G₁-Gₙ; an input terminal electrically connected to one of the data lines D₁-Dₘ; and an output terminal electrically connected to both the LC capacitor C_{LC} and the storage capacitor C_{ST}.

The LC capacitor C_{LC} includes a pixel electrode 190 provided on the lower panel 100 and a common electrode 270 provided on the upper panel 200 as two terminals. The LC layer 3 disposed between the pixel and common electrodes 190 and 270 functions as a dielectric of the LC capacitor C_{LC}. The pixel electrode 190 is electrically connected to the switching element Q, and the common electrode 270 is supplied with a common voltage Vcom and covers an entire surface of the upper panel 200. As an alternative to the embodiment shown in FIG. 2, the common electrode 270 may be provided on the lower panel 100, and the pixel and common electrodes 190 and 270 may have shapes of bars or stripes.

The storage capacitor C_{ST} is an auxiliary capacitor for the LC capacitor C_{LC}. The storage capacitor C_{ST} includes the pixel electrode 190 and a separate signal line, which is provided on the lower panel 100, overlaps the pixel electrode 190 via an insulator, and is supplied with a predetermined voltage such as the common voltage Vcom. Alternatively, the storage capacitor C_{ST} includes the pixel electrode 190 and an adjacent gate line called a previous gate line, which overlaps the pixel electrode 190 via an insulator.

For a color display, each pixel uniquely represents one of primary colors (i.e., spatial division) or each pixel sequentially represents the primary colors in turn (i.e., temporal division) such that spatial or temporal sum of the primary colors are recognized as a desired color. An example of a set of the primary colors includes red, green, and blue colors and optionally white (or transparency). Another example of a set of the primary colors includes cyan, magenta, and yellow, which can be employed with or without red, green, and blue colors. FIG. 2 shows an example of the spatial division in which each pixel includes a color filter 230 representing one of the primary colors in an area of the upper panel 200 facing the pixel electrode 190. Alternatively, the color filter 230 may be provided on or under the pixel electrode 190 on the lower panel 100.

One or more polarizers (not shown) are attached to at least one of the lower and upper panels 100 and 200.

Referring again to FIG. 1, the gray voltage generator 800 generates two sets of gray voltages related to a transmittance of the pixels. The gray voltages in a first set have a positive polarity with respect to the common voltage Vcom, while the gray voltages in a second set have a negative polarity with respect to the common voltage Vcom.

The gate driver 400 is electrically connected to the gate lines G₁-Gₙ of the panel assembly 300 and synthesizes a gate-on voltage Von and a gate-off voltage Voff from an external device to generate gate signals for application to the gate lines G₁-Gₙ. The gate driver 400 includes a gate driving integrated circuit (IC).

The data driver 500 is electrically connected to the data lines D₁-Dₘ of the panel assembly 300 and applies data voltages selected from the gray voltages supplied by the gray voltage generator 800, to the data lines D₁-Dₘ. The data driver 500 includes a plurality of data driving ICs.

The gate driving IC of the gate driver 400 or the data driving ICs of the data driver 500 may be implemented as integrated circuit (IC) chips mounted on the panel assembly 300 or on a flexible printed circuit (FPC) film in a tape carrier package (TCP) type, which are attached to the LC panel assembly 300. Alternatively, the gate and data drivers 400 and 500 may be integrated into the panel assembly 300 along with the display signal lines G₁-Gₙ and D₁-Dₘ and the switching elements Q. The signal controller 600 controls the gate driver 400 and the gate driver 500.

Operation of the above-described LCD device will be described in detail with reference to FIGS. 1 and 2.

The signal controller 600 is supplied with input image signals R, G and B and input control signals controlling a display of the LCD device. The input control signals include a vertical synchronization signal Vsync, a horizontal synchronization signal Hsync, a main clock MCLK, and a data enable signal DE, from an external graphics controller (not shown). After generating gate control signals CONT1 and data control signals CONT2 and processing the input image signals R, G and B suitable for operation of the panel assembly 300 in response to the input control signals and the input image signals R, G and B, the signal controller 600 transmits the gate control signals CONT1 to the gate driver 400, and both processed image signals DAT and the data control signals CONT2 to the data driver 500.

The gate control signals CONT1 include a scanning start signal STV for instructing the gate driver 400 to start scanning and a clock signal for controlling an output time of the gate-on voltage Von.

The data control signals CONT2 include a horizontal synchronization start signal STH for informing the data driver 500 of a start of data transmission for a group of pixels, a load signal LOAD for instructing the data driver 500 to apply the data voltages to the data lines D₁-Dₘ, and a data clock signal HCLK. The data control signal CONT2 may further include an inversion signal RVS for reversing a polarity of the data voltages (with respect to the common voltage Vcom).

Responsive to the data control signals CONT2 from the signal controller 600, the data driver 500 receives a packet of the processed image signals DAT for the group of pixels from the signal controller 600, converts the processed image signals DAT into analog data voltages selected from the gray voltages supplied by the gray voltage generator 800, and applies the data voltages to the data lines D₁-Dₘ.

The gate driver 400 applies the gate-on voltage Von to the gate lines G₁-Gₙ in response to the gate control signals CONT1 from the signal controller 600, thereby turning on selected switching elements Q. The data voltages applied to the data lines D₁-Dₘ are supplied to the pixels through turned on switching elements Q.

A difference between the data voltage and the common voltage Vcom is represented as a voltage across the LC capacitor C_{LC}, which is referred to as a pixel voltage. LC molecules in the LC capacitor C_{LC} have orientations that vary in response to a magnitude of the pixel voltage, and molecular orientations of the LC molecules determine a polarization of light passing through the LC layer 3. The polarizer(s) converts light polarization into light transmittance.

By repeating the above-described procedure each horizontal period (which is denoted by “1 H” and equal to one period of the horizontal synchronization signal, all gate lines G₁-Gₙ are sequentially supplied with the gate-on voltage Von during a frame, thereby applying the data voltages to all pixels. When a next frame starts after finishing one frame, the inversion control signal RVS applied to the data driver 500 is controlled such that the polarity of the data voltages is reversed (which is referred to as “frame inversion”). The inversion control signal RVS may be also controlled such that the polarity of the data voltages flowing in a data line in one frame are reversed (for example, line inversion and dot inversion), or the polarity of the data voltages in one packet are reversed (for example, column inversion and dot inversion).

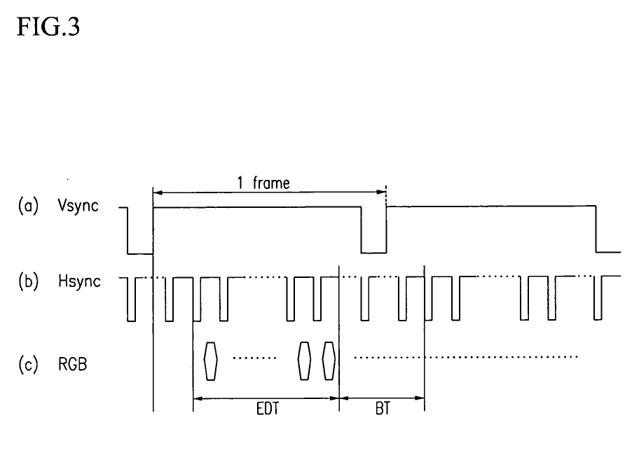

A driving method of an LCD device according to an exemplary embodiment of the present invention will be described in detail with reference to FIGS. 3 to 5.

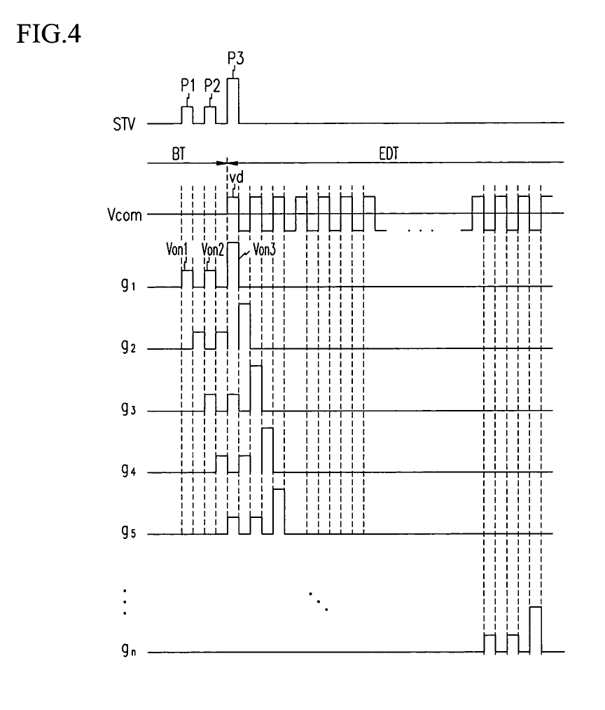

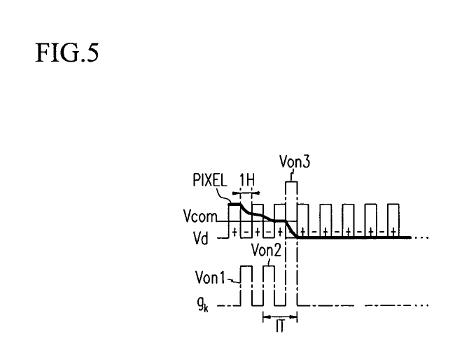

FIG. 3 illustrates waveforms of a vertical synchronization signal and horizontal synchronization signal when image signals are applied according to an exemplary embodiment of the present invention. FIG. 4 illustrates waveforms of a data voltage, a vertical synchronization signal and gate signals used in an LCD device according to an exemplary embodiment of the present invention. FIG. 5 illustrates a variation of a pixel electrode voltage with respect to a data voltage, when precharging gate-on voltages and a main charging gate-on voltage are applied according to an exemplary embodiment of the present invention.

An LCD device according to this embodiment of the present invention has a normally black mode, but a type of the LCD device may be varied.

Referring to FIG. 4, the gate-on voltage Von includes first and second precharging gate-on voltages Von1 and Von2, respectively, and a main charging gate-on voltage Von3. The first and second precharging gate-on voltages Von1 and Von2 have magnitudes substantially equal to each other. However, a number and a magnitude of precharging gate-on voltages may be varied, and the first and second precharging gate-on voltages Von1 and Von2 may have magnitudes different from each other. The first precharging gate-on voltage Von1 precedes the second precharging gate-on voltage Von2.

Each of the first and second precharging gate-on voltages Von1 and Von2 has a magnitude that creates an amount of a current flowing through a switching device Q activated by application of the first and second precharging gate-on voltages Von1 and Von2 that is less than an amount of a current flowing through the switching device Q activated by application of the main charging gate-on voltage Von3. For example, the magnitude of each of the first and second precharging gate-on voltages Von1 and Von2 is one half of a magnitude of the main charging gate-on voltage Von3.

However, the magnitude of each of the first and second precharging gate-on voltages Von1 and Von2 may be adjusted based on a magnitude of a data voltage Vd and a variation of a pixel electrode voltage PIXEL.

After output of the first precharging voltage Von1, a successive second precharging voltage Von2 is outputted after a predetermined horizontal period, for example, 2 H in case of 1 line inversion or 1×1 dot inversion, or a predetermined number of the gate lines G₁-Gₙ, for example, 2. However, an interval between the first precharging gate-on voltage Von1 and the second precharging gate-on voltage Von2 may be adjusted in response to a variation of the pixel electrode voltage PIXEL.

Alternatively, the number of the precharging gate-on voltages may be one or larger than three. However, when precharging gate-on voltages and main charging gate-on voltage are outputted, polarity of data voltages applied to one corresponding pixel electrode 190 should be substantially equal to each other. Thus an interval between precharging gate-on voltages is an even number times one horizontal period.

The scanning start signal STV includes first and second precharging pulses P1 and P2 for instructing the gate driver 400 to output the first and second precharging gate-on voltages Von1 and Von2, respectively, and a main charging pulse P3 for instructing the gate driver 400 to output the main charging gate-on voltage Von3. An interval between a preceding first precharging pulse P1 and a successive second precharging pulse P2 is equal to the interval between the first and second precharging gate-on voltages Von1 and Von2.

A height of the first precharging pulse P1 may be less than a height of the main precharging pulse P3, but may be larger than a height of the second precharging pulse P2.

Impulsive driving of an LCD device according to an exemplary embodiment the present invention will now be described in detail.

Application of the input image signals R, G and B from the external graphics controller will be described referring FIG. 3.

A vertical synchronization signal Vsync and a horizontal synchronization signal Hsync with a 1 frame period are applied to the signal controller 600. The signal controller 600 is supplied with the input image signals R, G and B corresponding to one frame based on the vertical and horizontal synchronization signals Vsync and Hsync.

A blank section BT is provided during which the input image signals R, G and B are not supplied. The blank section BT corresponds to a period before and after a segment of each frame during which the vertical synchronization signal Vsync maintains a low level. Thus, as shown in FIG. 3, for each frame, there is an effective data application section EDT during which the input image signals R, G and B are supplied and the blank section BT. In the exemplary embodiment shown in FIG. 3, each frame begins with a portion of a blank section of a previous frame and each frame ends with a portion of a blank section BT of the current frame.

Next, application of the analog data voltages corresponding to the processed image signals DAT to pixels will be described.

The signal controller 600 generates the first precharging pulse P1 of the scanning start signal STV applied to the data driver 400 during the blank section BT. The gate driver 400 supplied with the first precharging pulse P1 of the scanning start signal STV sequentially outputs the first precharging gate-on voltage Von1, to a first gate line G₁ electrically connected to a first output terminal of the gate driver 400, as shown by line g₁ in FIG. 4. A duration of the first precharging gate-on voltage Von1 is less than or equal to a duration of each of the data voltages Vd. Lines g₁ to gₙ illustrate signals transmitted to each of the corresponding gate lines G₁-Gₙ.

After a time substantially equal to 2 H elapses, the signal controller 600 generates the second precharging pulse P2 of the vertical synchronization signal STV. Responsive to the second precharging pulse P2, the gate driver 400 sequentially outputs the second precharging gate-on voltage Von2 from the first gate line G₁ electrically connected to the first output terminal of the gate driver 400. A duration of the second precharging gate-on voltage Von2 is substantially equal to the duration of the first precharging gate-on voltage Von1. However, durations of each of the first and second precharging gate-on voltages Von1 and Von2 may be different from each other as long as each of the first and second precharging gate-on voltages Von1 and Von2 is less than or equal to the duration of each of the data voltages Vd.

The first and second precharging gate-on voltages Von1 and Von2 supply the data voltages Vd transmitted every 2H to corresponding data lines D₁-Dₘ, by sequentially connecting respective pixel electrodes 190 to the first gate line G₁. Thus each corresponding pixel is precharged twice.

After output of the first precharging gate-on voltage Von1 to a fourth gate line G4, the blank section BT is finished and the effective data application section EDT starts. Thus, the signal controller 600 generates the main charging pulse P3 of the scanning start signal STV. It is preferable that a duration end time of the first and second precharging gate-on voltages Von1 or Von2 coincides with a start time of the efficient data application section EDT.

During the blank section BT, the signal controller 600 transmits processed image signals DAT for black color regardless of the input image signals R, G and B to the data driver 500, and the data driver 500 applies data voltages for the black color through the data lines D₁-Dₘ. Thus, the data voltages for the black color are applied to a corresponding pixel electrode 190 being supplied with a corresponding data voltage based on the first and second precharging gate-on voltages Von1 and Von2.

The gate driver 400 receives the main charging pulse P3 of the scanning start signal STV and sequentially outputs the main charging gate-on voltage Von3, to the first gate line G₁. Thus, pixel electrodes 190 electrically connected to each of the gate lines G₁-Gₙ are sequentially supplied with their own data voltages Vd. In other words, the pixels electrically connected sequentially from the first gate line G₁ are sequentially subjected to main charging to sequentially receive data voltages Vd.

For example, as shown in FIG. 4, if the first and second precharging gate-on voltages Von1 and Von2 have been already outputted to the first gate line G₁, and the main charging gate-on voltage Von3 is currently outputted to the first gate line. G₁, then the second precharging gate-on voltage Von2 is outputted to the third gate line G₃ and the first precharging gate-on voltage Von1 is outputted to the fifth gate line G₅. Thus, pixel electrodes 190 electrically connected to the third and fifth gate lines G₃ and G₅ are supplied with data voltages equal to data voltages Vd applied to pixel electrodes 190 electrically connected to the first gate line G₁.

By the above-described procedure, before main charging by the main charging gate-on voltage Von3, when the respective pixels are precharged before 2 H or two gate lines, variation of a pixel electrode voltage PIXEL being charged with a data voltage of positive polarity will be described with reference to FIG. 5.

As shown in FIG. 5, when the first and second precharging gate-on voltages Von1 and Von2 are sequentially generated at a gate signal gₖ outputted to a k-th gate line Gₖ, a switching device Q connected to a corresponding pixel electrode 190 is already turned on before application of the main charging gate-on voltage Von3, and thereby a pixel connected to the pixel electrode 190 is precharged by data voltage Vd having a negative polarity applied to the pixel electrode 190 through the turned on switching device Q.

Since a pixel electrode voltage PIXEL of the pixel electrode 190 has a positive polarity due to a data voltage having a positive polarity in a previous frame, the pixel electrode voltage PIXEL decreases because of the polarity difference.

Following application of the first precharging gate-on voltage Von1, the second precharging gate-on voltage Von2 is generated 2 H later, thus variation of the pixel electrode voltage PIXEL is accelerated. For example, the pixel electrode voltage PIXEL decreases to near a common voltage Vcom, and reaches the common voltage Vcom before the second precharging gate-on voltage Von2 is applied.

When a magnitude of a pixel voltage indicated as a difference between the pixel electrode voltage PIXEL and the common voltage Vcom is less than a predetermined voltage, for example, about 1V, transmittance of light passing the LC layer 3 is almost 0%, to display the black color on the LCD device. Additionally, when the magnitude of the pixel voltage is less than about 2V, a majority of light is not transmitted through the LC layer 3, to display a light black color on the LCD device. Therefore, although the pixel electrode voltage PIXEL is not equal to the common voltage Vcom, it is preferable that the difference between the pixel electrode voltage PIXEL and the common voltage Vcom is less than about 2V.

After a predetermined time elapses, when the main charging gate-on voltage Von3 is generated, the pixel is main changed by a data voltage Vd applied to the pixel electrode 190. Thus, the pixel electrode voltage PIXEL maintains an appropriate level corresponding to the data voltage Vd.

If the pixel voltage is less than about 2V, the LCD device displays the black color by variation of the pixel electrode voltage PIXEL by the first and second precharging gate-on voltages Von1 and Von2. Thus, an impulsive section IT shown in FIG. 5 may be from a time that the pixel voltage is less than about 2V to a time that the main charging gate-on voltage Von3 is applied.

As described above, the number of the precharging voltages may be one or more and may be defined based on the magnitude of the pixel electrode voltage PIXEL applied in a previous frame.

The pixel voltage related to the corresponding pixel maintains about 2V or less by applying the first and second precharging gate-on voltages Von1 and Von2 at a predetermined interval. Thus, a number of precharging voltages may increase as the difference between the pixel electrode voltage PIXEL and the common voltage Vcom become larger.

As described above, the pixel electrode voltage PIXEL is adjusted to near the common voltage Vcom based on the magnitudes of the first and second precharging gate-on voltages Von1 and Von2, to vary light transmittance in response to the pixel voltage for impulsive driving.

An interval between an output time of a last precharging gate-on voltage of a plurality of precharging gate-on voltages and an output time of a successive main charging gate-on voltage may be adjusted in consideration of the impulsive section IT. In other words, as an interval between the output time of the last precharging gate-on voltage and the output time of the successive main charging gate-on voltage becomes larger, the impulsive section IT becomes longer.

When an inversion type is N row inversion or N×M dot inversion, after output of the main charging gate-on voltage, a precharging gate-on voltage is transmitted to a (2N+1)th gate line if a number of the precharging gate-on voltages is one, a first precharging gate-on voltage is transmitted to(2N+3)_th gate line if the number of the precharging gate-on voltage is two, and the first precharging gate-on voltage is transmitted to(2N+5)_th gate line if the number of the precharging gate-on voltage is three. In other words, if the number of the precharging gate-on voltages is r, the first precharging gate-on voltage is outputted to the [(2N)+(2r-1)]_th gate line. (Here, N, M and r=1,2, . . . ).

The gate driver 400 outputs a precharging gate-on voltage and a main charging gate-on voltage by determining heights of the precharging pulses P1 and P2 and the main charging pulse P3.

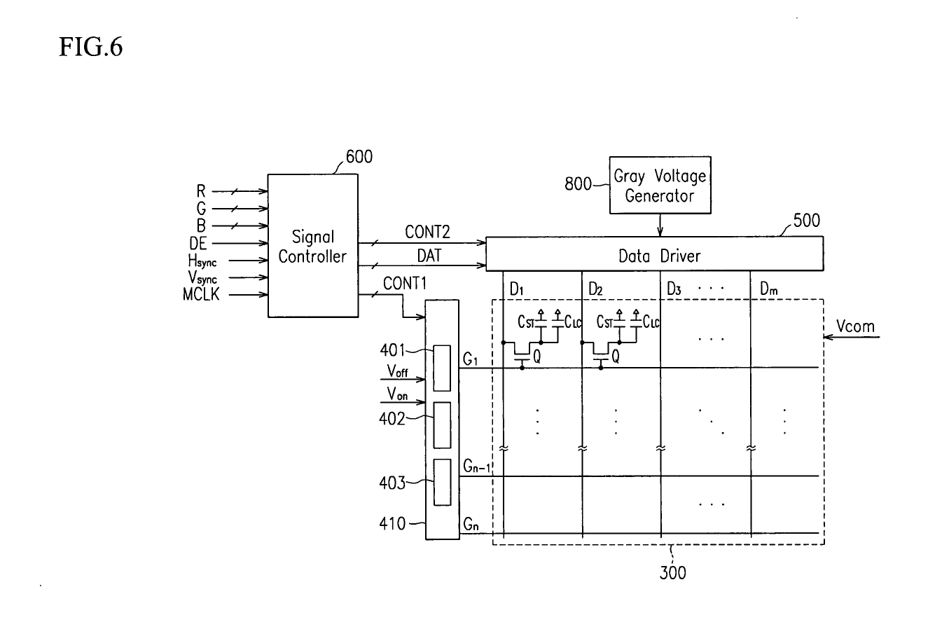

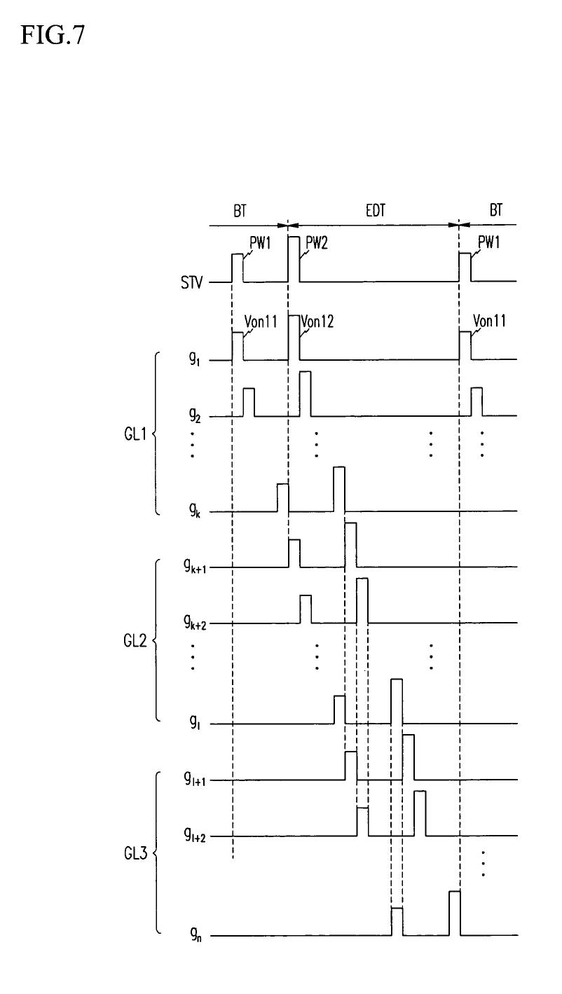

A driving method of an LCD device according to another exemplary embodiment of the present invention will be described in detail with reference to FIGS. 6 and 7.

FIG. 6 is a block diagram of an LCD device according to another exemplary embodiment of the present invention, and FIG. 7 illustrates waveforms of a vertical synchronization signal and gate signals used in an LCD device according to another exemplary embodiment of the present invention.

The LCD device shown in FIG. 6 has the substantially the same configuration of the LCD device shown in FIG. 1 except a gate driver 410. Specifically, the gate driver 410 shown in FIG. 6 includes a first gate driving IC 401, a second gate driving IC 402, and a third gate driving IC 403. As shown in FIG. 7, the gate lines G₁-Gₙ are grouped into a first gate line group GL1, a second gate line group GL2, and a third gate line group GL3 electrically connected to the first, second and third gate driving ICs 401-403, respectively. A number of the gate driving ICs may be varied as necessary.

A driving operation of an LCD device will now be described in detail.

The signal controller 600 generates a precharging pulse PW1 of a scanning start signal STV applied to the first gate driving IC 401 for a blank section BT, for example, at a time at which the blank section BT is started.

The first gate driving IC 401 applies the precharging pulse PW1 and sequentially outputs a precharging gate-on voltage Von11, from the first gate line G₁ electrically connected to a first output terminal of the first gate driving IC 401 to a k_th gate line Gₖ connected to a k_th output terminal of the first gate driving IC 401, and then outputs a first carry signal to the second gate driving IC 402. Simultaneously with the output of the first carry signal, the signal controller 600 generates a main charging pulse PW2 of the scanning start signal STV.

Switching elements Q corresponding from the first gate line G₁ of the first gate line group GL1 are sequentially turned on by the precharging gate-on voltage Von11. The data driver 600 transmits data voltages for the black color to the data lines D₁-Dₘ during the blank section BT, to precharge pixels to data voltages for the black color.

Next, responsive to the precharging pulse PW1 of the scanning start signal STV, the first gate driving IC 401 sequentially outputs a main charging gate-on voltage Von12 from the first gate line G₁ electrically connected to the first output terminal of the first gate driving IC 401. In addition, the second gate driving IC 402 receiving the first carry signal sequentially outputs the main charging gate-on voltage Von12 to a gate line Gₖ₊₁ electrically connected to a first output terminal of the second gate driving IC 402 to a gate line G₁ electrically connected to a last output terminal of the second gate driving IC 402. Accordingly, pixel electrodes electrically connected to the gate lines G₁-Gₖ of the first gate line group GL1 are sequentially supplied with data voltages from the data driver 500 by the main charging gate-on voltage Von12, to main charge pixels corresponding to the pixel electrodes 190. During this time, pixel electrodes 190 which are electrically connected to the gate lines Gₖ₊₁-G₁ of the second gate line group GL2, are simultaneously supplied with data voltages applied to the pixel electrodes 190 electrically connected to the first gate line group GL1 by the precharging gate-on voltage Von11, to precharge pixels corresponding to the pixel electrodes 190.

By scanning as described above, the first gate driving IC 401 outputs a second carry signal to the second gate driving IC 402, after the output of the main charging gate-on voltage Von12 to the last gate line Gₖ of the first gate line group GL1, and simultaneously the second gate driving IC 402 outputs the first carry signal to the third gate driving IC 403.

Thus, the second gate driving IC 402 outputs the main charging gate-on voltage Von12 sequentially from a first gate line Gₖ₊₁ of the second gate line group GL2 and the third gate driving IC 403 outputs the precharging gate-on voltage Von11 sequentially from a first gate line Gᵢ₊₁ of the third gate line group GL3.

As described above, if the gate driver 410 includes a plurality of gate driving ICs 401-403, the scanning of one gate driving IC electrically connected to a corresponding gate line group is carried out, and simultaneously pixel electrodes 190 electrically connected to a next gate line group are supplied with data voltages before the scanning of the next gate line group for main charging. Therefore, the difference between the pixel electrode voltage and the common voltage is less than a predetermined voltage, for example, about 2V, and thus the pixels corresponding to the pixel electrodes represent the black color before being supplied with their own data voltages. In other words, without supplying separate data voltages for impulsive driving, the impulsive driving is carried out by adjusting light transmittance using the pixel voltage.

As an alternative to the embodiment shown in FIG. 6, the signal controller 600 may include one or more precharging pulses of the scanning start signal STV and the gate driving IC may generate one or more precharging voltages. In this case, the number of the precharging voltages is defined in accordance with the difference between the pixel electrode voltage and the common voltage, which is applied for a previous frame.

Moreover, in case that the inversion type is N row inversion, the number of gate lines of the respective gate driving IC is (2N× integral times), thereby the precharging voltage is outputted to (2N× integral times)+1_th gate line. As described above, a polarity of the precharging voltage and the main charging voltage are equal to each other. The blank section should be maintained at least until a finish time of the scanning of all gate lines electrically connected to one gate driving IC.

In the exemplary embodiments of the present invention, though the gate drivers 400 and 410 output main charging voltage or precharging voltage based on the scanning start signal STV including pulses of different heights, but may be supplied with a main charging pulse and a precharging pulse from the signal controller, and selectively output the main charging voltage or the precharging voltage in response to the scanning start signal.

Moreover, the gate-on voltage applied to the data driver may have levels for main charging voltage and precharging voltage. In such a case, heights of pulses generated in the scanning starting signal STV are equal to each other, and the gate driver may output the main charging voltage and precharging voltage based on levels of the gate-on voltage in generating of the pulses in the scanning start signal STV.

In impulsive driving according to the exemplary embodiments of the present invention, a separate data voltage for the impulsive driving is unnecessary and a charging time of a pixel does not decrease. Additionally, since a separate data voltage for impulsive driving is unnecessary, the operation and configuration of display devices become simple and a data processing speed increases.

In addition, since the charging time of a pixel dose not decrease, image quality deterioration of display devices due to shortened charging time decreases.

While the present invention has been described in detail with reference to the exemplary embodiments, it is to be understood that the invention is not limited to the disclosed embodiments, but, on the contrary, is intended to cover various modifications and equivalent arrangements included within the sprit and scope of the appended claims.

What is claimed is:

1. A display device comprising:
gate lines transmitting a first gate-on voltage and a second gate-on voltage, a magnitude of the second gate-on voltage being different than a magnitude of the first gate-on voltage;
data lines transmitting data voltages;
pixels including switching elements and pixel electrodes, the switching elements being electrically connected to corresponding ones of the gate lines and the data lines, the switching elements configured to turn on in response to the first and second gate-on voltages, and the pixel electrodes supplied with the data voltages;
a gate driver electrically connected to the gate lines and sequentially applying the first and second gate-on voltages to the gate lines; and
a data driver applying the data voltages to the data lines,
wherein the gate driver outputs the first gate-on voltage before the second gate-on voltage.

2. The device of claim 1, wherein the magnitude of the first gate-on voltage is less than the magnitude of the second gate-on voltage.

3. The device of claim 2, wherein the switching elements each pass a current responsive to the first and second gate-on voltages, and an amount of the current flow responsive to the first gate-on voltage is less than an amount of the current flow responsive to the second gate-on voltage.

4. The device of claim 3, wherein after application of the first gate-on voltage, a pixel electrode voltage applied to the pixel electrodes has a magnitude near a magnitude of a common voltage.

5. The device of claim 4, wherein a difference between the pixel electrode voltage and the common voltage is less than a predetermined value.

6. The device of claim 5, wherein the difference between the pixel electrode voltage and the common voltage is less than about 2V.

7. The device of claim 4, wherein the gate driver transmits the first gate-on voltage.

8. The device of claim 7, wherein in response to the first gate-on voltage being applied to the switching elements, the pixel electrodes receive a data voltage having a polarity different from a polarity of a previous charged voltage through the switching elements.

9. The device of claim 8, further comprising:
a signal controller controlling the gate driver and the data driver,
wherein the signal controller supplies a scanning start signal for instructing the gate driver to start to output the first and second gate-on voltages.

10. The device of claim 9, wherein the device has an N-row inversion type, and the gate driver transmits the first gate-on voltage about (2N)H (here, H denotes a period of a horizontal synchronization signal from the signal controller) before transmission of the second gate-on voltage.

11. The device of claim 9, wherein the scanning start signal comprises a first pulse for instructing the gate driver to start to output the first gate-on signal and a second pulse for instructing the gate driver to start to output the second gate-on signal.

12. The device of claim 11, wherein the gate driver outputs the first and second gate-on signals by determining respective heights of the first and second pulses.

13. The device of claim 8, wherein the gate driver comprises gate driving integrated circuits,
wherein the gate lines comprise gate line groups electrically connected to output terminals of the respective gate driving integrated circuits, and
wherein the respective gate driving integrated circuits output the first gate-on voltage to respective gate line groups before outputting the second gate-on voltage.

14. The device of claim 1, wherein the device is a liquid crystal display (LCD) device.

15. The device of claim 14, wherein the LCD device includes a normally black mode.

16. A driving method of a display device including switching elements electrically connected to gate lines and data lines and pixel electrodes electrically connected to the switching elements, the method comprising:
applying first data voltages to the data lines;
applying the first data voltages to the pixel electrodes through the switching elements by applying a first gate-on voltage to the gate lines;
applying second data voltages to the data lines; and
applying the second data voltages to the pixel electrodes through the switching elements by applying a second gate-on voltage to the gate lines,
wherein a magnitude of the first gate-on voltage is different from a magnitude of the second gate-on voltage.

17. The method of claim 16, wherein the magnitude of the first gate-on voltage is less than the magnitude of the second gate-on voltage.

18. The method of claim 16, wherein the switching elements each pass a current responsive to the first gate-on voltage and the second gate-on voltage, and an amount of the current flow responsive to the first gate-on voltage is less than an amount of current flow responsive to the second gate-on voltage.

19. The method of claim 18, wherein after application of the first gate-on voltage, a pixel electrode voltage applied to the pixel electrodes has a magnitude near a magnitude of a common voltage.

20. The method of claim 18, wherein the applying the first data voltages to the pixel electrodes through the switching elements by applying a first gate-on voltage to the gate lines further comprises applying a data voltage having a polarity different from a polarity of a previous charged voltage through the switching elements.
